(19) United States
(12) Patent Application Publication
(10) Pub. No.: US 2018/0158689 A1
(43) Pub. Date: Jun. 7, 2018

(54) METHOD OF SMOOTHING A SURFACE

(71) Applicant: SPTS TECHNOLOGIES LIMITED, Newport (GB)

(72) Inventor: ROLAND MUMFORD, CARDIFF (GB)

(21) Appl. No.: 15/830,969

(22) Filed: Dec. 4, 2017

(30) Foreign Application Priority Data
Dec. 5, 2016 (GB) 1620680.7

(51) Int. Cl. H01L 21/3065; H01L 21/67; H01L 21/768

(52) U.S. Cl. CPC H01L 21/3065; H01L 21/76898; H01L 21/67069

(57) ABSTRACT

According to the invention there is provided a method of smoothing a surface of a silicon substrate comprising the steps of: providing a silicon substrate having a backside surface, wherein the silicon substrate has been ground to leave the backside surface with an associated roughness; and smoothing the backside surface of the silicon substrate using a plasma etch process; in which the plasma etch process comprises the steps of performing a first plasma etch step which forms a plurality of protrusions that upstand from the backside surface; and performing a second plasma etch step which at least partially etches the protrusions to provide a smoothed backside surface which exhibits specular reflection.

This invention relates to a method of smoothing a surface of a silicon substrate.

In many semiconductor applications, it is desirable to manufacture devices on thin silicon substrates. The reasons for this desirability include form factor and performance considerations. In practice, the device is typically formed on a conventional silicon wafer. For example, a 300 mm diameter silicon wafer is typically about 765 microns thick. Once the device manufacture steps are completed, the wafer is ground down to the final device thickness using conventional grinding equipment. The rate of removal and surface finish can be controlled by standard procedures, although both factors are dependent on the grinding wheels and the abrasives used. Once the grinding step is completed, the grounded surface is polished to meet the required specification of the device manufacturer. The polishing step can also remove material that has been damaged by the aggressive grinding operation. In turn, this can improve the mechanical properties of the substrate and the eventually produced die.

With vertically stacked semiconductor dies, wafers are ground back to remove the bulk of the wafer thickness before integrating devices in a three dimensional stack. In some schemes, such as through silicon vias (TSVs), the buried copper TSVs are revealed by a plasma or wet etch ‘via reveal’ step which follows the removal of bulk silicon in the grinding step.

The grinding process produces radial scratch patterns that are visible both to the eye and also to inspection equipment. This can result in spurious defect detection and hence loss of yield. The scratches are less than 100 nm in depth, but are reasonably visible to the naked eye. Therefore, it is necessary to improve the surface finish of the ground wafer to enable the subsequent use of conventional optical inspection equipment. Current solutions to this problem rely on chemical and mechanical planarization (CMP) to remove scratches before a plasma etching step. The CMP process is expensive, time consuming, and suffers from repeatability problems. One study suggests that almost 50% of the cost of TSV reveal processes are associated with CMP (http://www.3dincites.com/2016/03cost-analysis-of-a-wet-etch-tsv-reveal-process/).

From the forgoing discussion, it can be seen that there is a need to eliminate the CMP step in the processing of ground silicon substrates. This would have the desirable effect of eliminating the associated and expensive CMP equipment and consumables. The problem is to eliminate the CMP step whilst obtaining at least acceptable smoothness of the processed silicon substrate.

The present invention, in at least some of its embodiments, addresses the above described desires and problems.

According to a first aspect of the invention there is provided a method of smoothing a surface of a silicon substrate comprising the steps of:

providing a silicon substrate having a backside surface, wherein the silicon substrate has been ground to leave the backside surface with an associated roughness: and

smoothing the backside surface of the silicon substrate using a plasma etch process;

in which the plasma etch process comprises the steps of:

performing a first plasma etch step which forms a plurality of protrusions that upstand from the backside surface; and

performing a second plasma etch step which at least partially etches the protrusions to provide a smoothed backside surface which exhibits specular reflection.

In this way, it is possible to avoid an undesirable CMP step whilst delivering at least acceptable results. In general, the invention is performed without performing a CMP step.

Typically, the second etch step is performed to substantially remove the protrusions.

The first and second plasma etch steps may be alternately repeated. The first and second plasma etch steps may be alternately repeated any number of times to achieve a desired finish.

Alternatively, a single first and/or a single second plasma etch step may be performed.

The first plasma step may be an isotropic etch process.

The first plasma etch step may be performed using no RF bias.

The first etch step may be performed using an RF bias power of less than 100 W.

The first plasma etch step may use a gas mixture comprising oxygen and at least one etchant precursor gas. The first plasma etch step may use flows of the etchant precursor gas and oxygen at associated flow rates. The flow rate of oxygen may be greater than the flow rate of the etchant precursor gas. The flow rate of oxygen may be at least three times the flow rate of the etchant precursor gas. The flow rate of oxygen used in relation to the flow rate of the etchant precursor gas may be selected so as to ensure that polymeric species are not deposited on the substrate during the first etch step.

The first plasma etch step may use a fluorine containing etchant precursor gas. The fluorine containing etchant precursor gas may be SF₆. Alternatively, the fluorine containing etchant precursor gas may be CF₄.

The first plasma etch step may be performed at a pressure in the range 100-500 mTorr.

The first plasma etch step may produce a plurality of deposits on the back side surface which act to mask the protrusions.

The second plasma etch step may use a fluorine containing etchant precursor gas. The fluorine containing etchant precursor gas may be SF₆ or CF₄.

Other etch chemistries may be employed in the second etch step. For example, chlorine based etch chemistries might be used. In these embodiments, the second plasma etch step may use a chlorine containing etchant precursor gas.

The second etch step may be performed in the substantial absence of oxygen.

The second plasma etch step may use a Noble gas as a process gas. The Noble gas may be argon. Without wishing to be limited by any particular theory or conjecture, it is believed that the sputtering associated with the Noble gas may enhance the removal of any deposits on the back side surface which act to mask the protrusions.

An RF bias power may be used during the second plasma etch step. The RF bias power used during the second plasma etch step may be greater than 500 W. Preferably, the RF power used is greater than 700 W.

In embodiments in which the first and second plasma etch steps are alternately repeated, the etch conditions associated with the first etch step and/or the second etch step may remain the same. Examples of etch conditions comprise RF source power, gas flow rates, etch time and gas pressure. However, it is also within the scope of the invention for the etch conditions associated with the first etch step and/or the second etch step to change as the plasma etch process proceeds. The skilled reader will appreciate that there are an unlimited number of variations possible. In general, a plasma etch process is selected to best match any given end application and system. For example, the first etch step and/or the second etch may change smoothly over the course of the plasma etch process by smoothly varying one or more of the associated etch conditions. Alternatively, or additionally, there may be an abrupt change in the first and/or second etch step by abruptly varying one or more of the associated etch conditions.

The first plasma etch step may comprise two or more different first etches, wherein each of the first etches has different associated etch conditions. Additionally, or alternatively, the second plasma etch step may comprise two or more different second etches, wherein each of the second etches has different associated etch conditions. One of the second etches may be a polish etch step. The polish etch step may at least partially etch the protrusions at a higher etch rate than the others of the second etches. The polish etch step may be performed using a higher gas pressure than the others of the second etches. The polish etch step may be similar to or identical to the process described in the Applicant's patent application US 2015/0287637 for revealing features such as vias buried in a silicon substrate. The entire contents of US 2015/0287637 are herein incorporated by reference.

In general, the polish etch step is performed as the last second etch step. This may be achieved by providing a polish etch step as a discrete second etch step at the end of the plasma etch process. Alternatively, the first and second etch steps may be alternately repeated so that the second plasma etch step comprises two or more different second etches, and the last of the second etches performed is a polish etch step.

The plasma etch process may reduce the thickness of the substrate by 2.5 microns or less.

The plasma etch process results in a reduction of the thickness of the substrate. The first plasma etch step may account for less than 20% of the reduction.

Prior to the step of smoothing, the backside surface may have a topography with a height variation of 100 nm or less.

The step of smoothing may be performed so that the backside surface has a topography with a height variation of 25 nm or less.

The silicon substrate provided may have a periodic scratch pattern on the backside surface. The step of smoothing may be performed so as to remove the periodic scratch pattern. The periodic scratch pattern may comprise a plurality of grooves which are imparted by the grinding process used previously to grind the silicon substrate.

The substrate may contain buried features such as vias. The method may further comprise the step of performing a buried feature reveal process subsequent to the step of smoothing. Advantageously, the steps of smoothing and performing the buried feature reveal process may be performed sequentially in a common chamber. It is a considerable advantage of the invention that it is possible to perform sequential smoothing and buried feature reveal processes on a silicon substrate disposed in a common chamber with the substrate remaining in the common chamber between the step of smoothing and the step of performing a buried feature reveal process.

The protrusions may present themselves as spires of silicon.

The protrusions may present themselves as grass-like formations.

Typically, the silicon substrate is a silicon wafer. A wafer of any desired diameter might be used.

Generally, the silicon substrate provided has a front side surface with one or more device structures formed thereon.

According to a second aspect of the invention there is provided an apparatus for smoothing a surface of a silicon substrate using a method according to a first aspect of the invention, the apparatus comprising:

a chamber in which the plasma etch process is performed;

one or more plasma production devices for producing plasmas suitable for performing the first and second plasma etch steps; and

a controller configured to control the apparatus to perform the method according to the first aspect of the invention.

Whilst the invention is described above, it extends to any inventive combination of the features set out above or in the following description, drawings or claims. For example, any feature described in relation to the first aspect of the invention is also disclosed in combination with the second aspect of the invention and vice versa.

The invention may be performed in various ways, and, by way of example only, embodiments thereof will now be described with reference to the accompanying drawings, in which:—

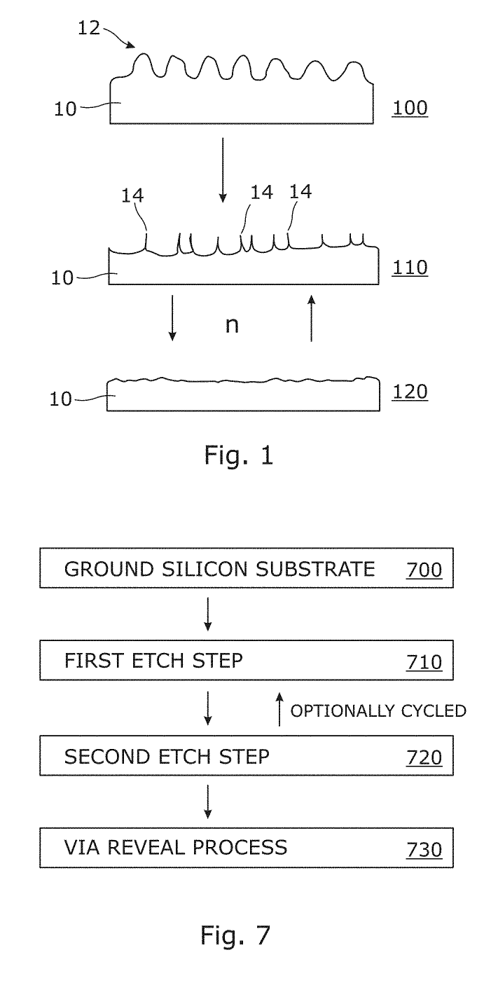

FIG. 1 shows steps in an embodiment of the invention;

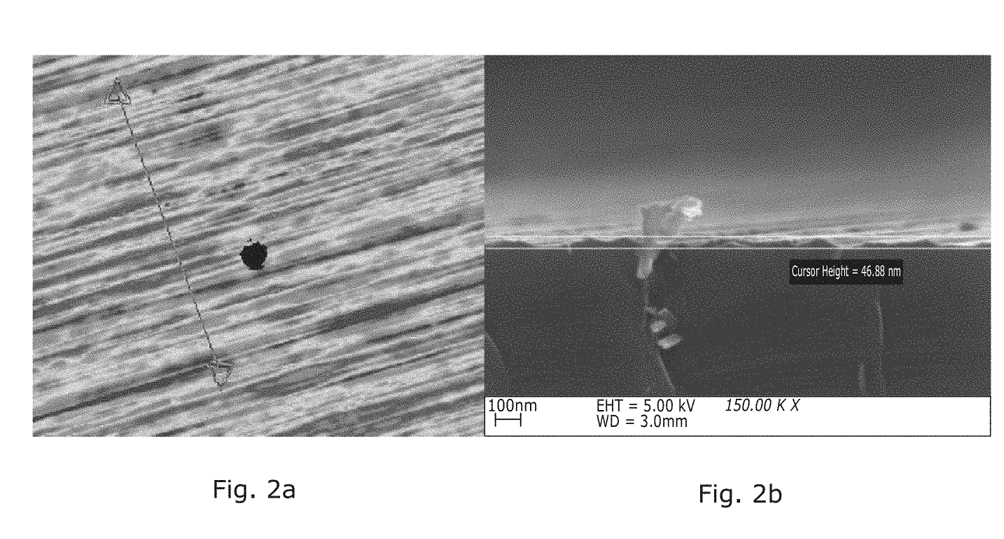

FIG. 2 shows (a) an image and (b) a SEM micrograph of the surface of a ground silicon wafer;

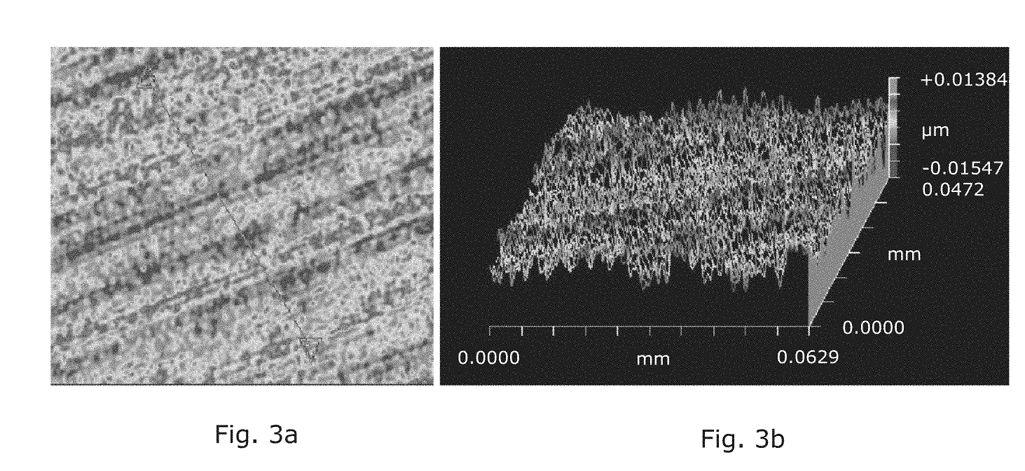

FIG. 3 shows (a) a two dimensional view and (b) a three dimensional representation of the surface of the silicon wafer after a first etch step to produce protrusions;

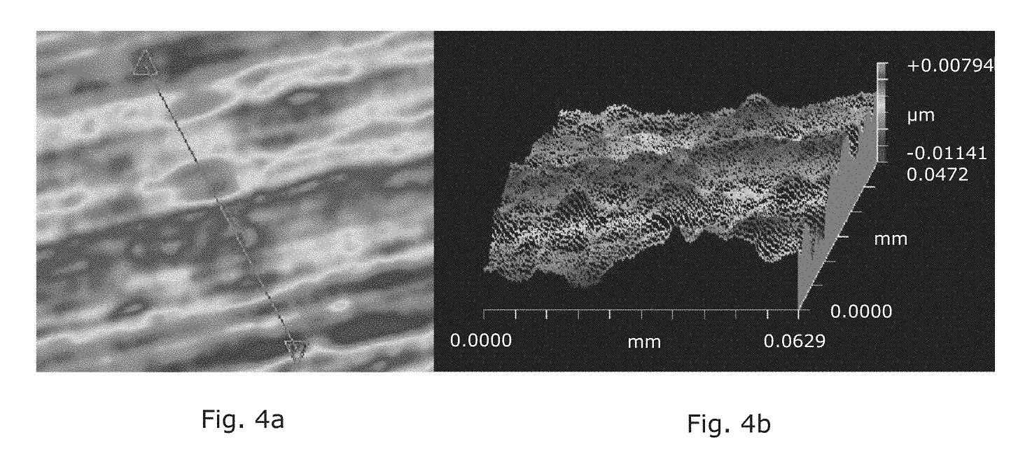

FIG. 4 shows (a) a two dimensional view and (b) a three dimensional representation of the surface of the silicon wafer after a cyclical etch process comprising alternate first and second etch steps;

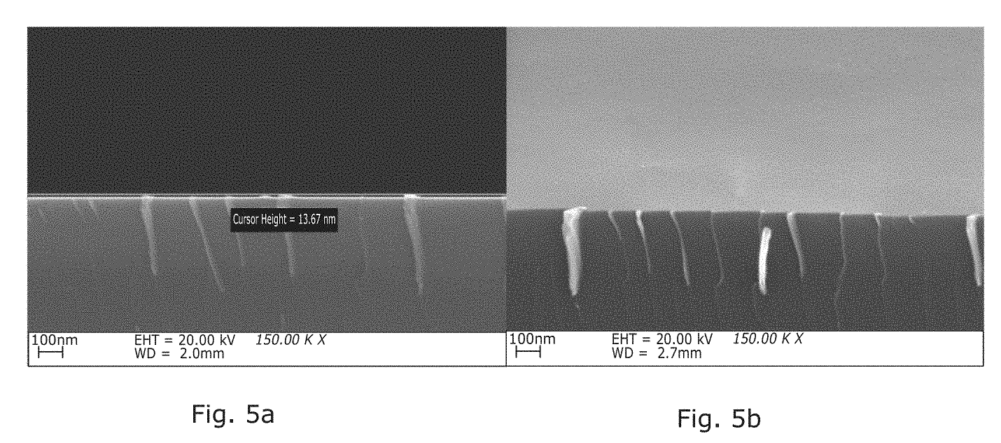

FIGS. 5 (a) and (b) shows SEM micrographs of a cross section of the silicon wafer after the cyclical etch treatment;

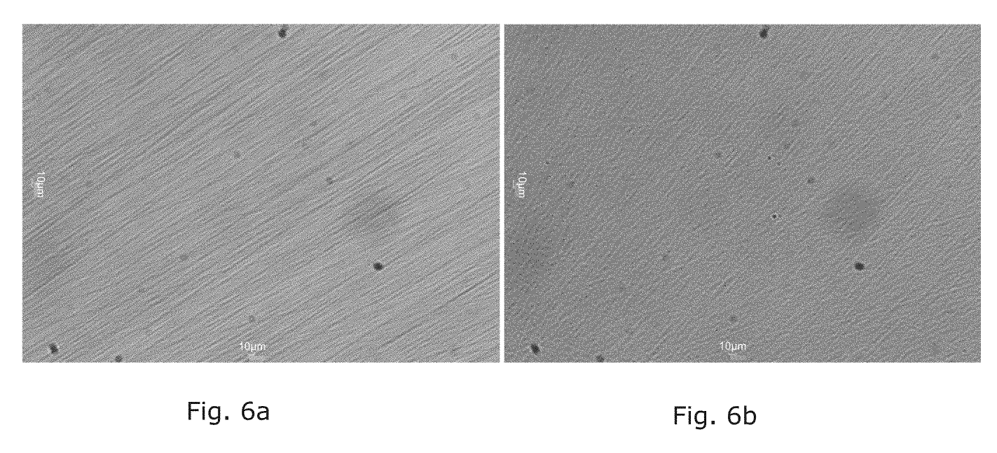

FIG. 6 shows optical micrographs of (a) the surface of the ground silicon wafer prior to etch treatment of the invention and (b) the surface of the silicon wafer after the etch treatment of the invention; and

FIG. 7 shows an embodiment in which wafer smoothing by etching is combined with a via reveal process.

FIG. 1 depicts steps in a process of the invention. In a first step 100, a silicon substrate 10 is supplied for processing. Typically, the silicon substrate is a wafer. The substrate 10 is a thinned substrate which has been thinned by grinding. This grinding process imparts a surface roughness 12. The invention provides a way of smoothing the surface roughness using a plasma etch process which is described below.

In a first plasma etch step 110, the rough surface of the substrate 10 is etched to produce a plurality of protrusions 14. Then, in a second etch step 120, the protrusions are etched back to provide a surface 16 which is smoother than the surface of the thinned substrate prior to commencement of the etch process. The first etch step 110 and the second etch step 120 can each be performed once only so that the etch process consists of two discrete etch steps. However, it is also possible to perform a looped, or cyclical etch process where the first and second etch steps are alternately repeated a number of times. In FIG. 1, this is shown as n cycles. There is no fundamental limitation on the number n of cycles performed—this will be determined process optimisation for any given process scenario.

By way of example only, process conditions will now be described for an embodiment of the invention. In this embodiment, both the first and second etch steps use SF₆ as a process gas. Whilst this is convenient from a process point of view, it is not necessary that common process gases are used in the first and second etch steps. In the first etch step, an oxygen rich mixture of SF₆, oxygen and a trace amount of argon is used. No RF bias is applied and a relatively high pressure of 250 mTorr is used. The first etch step is isotropic. In the second etch step, a mixture of SF₆, argon and a trace amount of oxygen is used. An RF bias is applied and a substantially lower pressure of 20 mTorr is used. The process conditions are shown in Table 1.

TABLE 1
Typical process conditions for a looped process.

| Process | | Second | First Etch |
|---|---|---|---|
| Condition | Strike | Etch Step | Step |
| Pressure | 20 | 20 | 250 |
| (mT) | | | |
| RF Source | 1.5 | 1.5 | 2.5 |
| (kW) | | | |
| RF bias | 0 | 0.75 | 0 |
| (kW) | | | |
| Process | 400 | 400 | 1 |
| Gas-Ar (sccm) | | | |
| Process | 150 | 150 | 100 |
| Gas-SF6 (sccm) | | | |
| Process | 1 | 1 | 500 |
| Gas-O2— (sccm) | | | |

In this example the RF source power, gas flows, and gas pressure all remain the same between the loops. However, they could be different for different loops or change over the total time of the process. Table 1 merely details some typical process conditions used for this process. For example, the looped process can be applied to lower power and/or gas flow conditions.

The loop times can be chosen to achieve the optimal ratio for initial roughness. Typical loop times are 30 s for the first etch step and 10 s for the second etch step. However, a range of 2 s to 600 s for the loop times is believed to be practical. The RF bias power used could be at a continuous level or pulsed. Other parameters such as RF source power and gas flows might be at a continuous level or pulsed. The process times of the individual etch steps and bias powers could also change as a function of the total process time. The process can be carried out using known etch tools which can be adapted using the teachings provided herein to perform the invention. The applicant's own Pegasus etch module can be adapted in this way.

Ground silicon wafers were processed in accordance with the invention and their surface characteristics analysed. Silicon wafers of 300 mm diameter were used in these experiments. The surface roughness of the incoming ground wafers was characterised using a Zygo white light interferometer and by SEM (scanning electron microscopy) using cleaved pieces of wafers. In FIG. 2(a) we can see the optical appearance of a silicon wafer after the grind step. In FIG. 2(b) the SEM micrograph clearly shows the grind marks on the wafer surface with a range of ˜47 nm. Wafers with local roughness of up to ˜100 nm have been processed successfully. Periodic grooves on the surface are clearly recognisable. These grooves are imparted during the grinding process. The grooves are visible to the naked eye and, importantly, to conventional inspection equipment. This can give rise to spurious defect detection unless steps are taken to improve the surface roughness—in particular to reduce or eliminate the pattern of grooves.

FIGS. 3(a) and (b) show the wafer surface after a first etch step has been performed. This step can be regarded as a surface-roughening step, and it results in the creation of a plurality of protrusions. This can be seen in FIG. 3 as a large number of fine spires of silicon, in this case of the order of 30 nm high. To highlight the features these measurements were made after a prolonged 5 min surface roughening step. This gives the silicon surface a ‘grassy’ appearance. The creation of the ‘grassy’ surface is a mechanism by which the regular scratch pattern previously created by grinding can be disrupted. The second etch step can be regarded as a break-through step which polishes the surface through reduction of the roughened surface.

By repeating this process for a variable number of loops depending on initial surface roughness, a visually smooth (no scratches visible by eye) surface is created. FIGS. 4(a) and (b) show the wafer surface after receiving a number of loops of the process. There are no visible spires of silicon and whilst the roughness is still around 20 nm the grooves caused by grinding have merged and no scratches are seen by eye. As noted previously, this criterion was chosen as this optically smooth surface is needed to pass automated inspection equipment which mistakes grind marks as process defects. SEM cross sections of post etch surfaces at an equivalent magnification to that used in FIG. 2(b) (150 kX) are presented in FIGS. 5 (a) and (b). These images show a virtually featureless surface with topography<14 nm in height. The original grind pattern has been dramatically reduced resulting in a specular wafer surface which has improved reflectivity.

FIGS. 6 (a) and (b) shows optical micrographs of the surface topography of the wafer before and after the etch smoothing process is employed. This confirms that the randomization of scratches on the surface eliminates visible scratches. As a consequence of this process standard automated inspection equipment do not mistakenly identify the treated ground surface as defective.

Typically, around 2 microns of silicon is removed using the etch process, with about 0.3 micron being removed due to the first (grass formation) etch step. Etch rates of >1.2 mm/min are achievable. However, these values are representative only. It is possible that the smoothing provided by the invention may also provide some stress relief for the substrate as well.

Without wishing to be bound by any particular theory or conjecture, we speculate that the protrusions are formed during the surface roughening step due to micromasking. Further, we speculate that the micromasking features are non-polymeric in nature and are caused by sulphur containing compound(s). By operating at a relatively high pressure in an oxygen rich environment with little or no RF bias, it is believed that the plasma chemistry is non-polymeric. It is believed also that this is a favorable regime for controlling the density of the micromasking features. The etch step uses lower pressure and RF bias coupled with Ar to help remove the micromasking materials and provide SF6 to remove silicon.

As mentioned above, the etch conditions associated with the first etch step and/or the second etch step may change as the plasma etch process proceeds. The skilled reader will appreciate that there are an unlimited number of variations possible and, in general, a plasma etch process is selected to best match any given end application and system. Also, within a loop, the first plasma etch step may comprise two or more different first etches, wherein each of the first etches has different associated etch conditions. Additionally, or alternatively, within a loop the second plasma etch step may comprise two or more different second etches, wherein each of the second etches has different associated etch conditions. In a non-limiting example, a process of the invention may comprise n loops, where each loop is made up of first etch 1A, second etch 2A, first etch 1B and second etch 2B, performed in that order. Etches 1A and 1B together comprise the first plasma etch step, whereas etches 2A and 2B together comprise the second plasma etch step. One of the second etches (preferably the second etch 2B) may be a polish etch step which etches the protrusions at a higher etch rate than the others of the second etches. Other variations (using loops comprising fewer or more etches) will suggest themselves to the skilled reader. The polish etch step may be similar to or identical to the process described in the Applicant's patent application US 2015/0287637. In general, the polish etch step is performed as the last second etch step.

FIG. 7 shows an advantageous aspect of the invention in which the substrate contains buried features such as vias. In this aspect, smoothing of the substrate surface is combined with a via reveal process, with all of the steps being performed in a single chamber of a single process tool. This provides significant processing advantages. In a first step 700, a thinned silicon substrate is supplied for processing. In a first plasma etch step 710, the rough surface of the substrate is etched to produce a plurality of protrusions 14. In a second etch step 720, the protrusions are etched back to provide a surface which is smoother than the surface of the thinned substrate prior to commencement of the etch process. Then, a process 730 is performed in the same chamber in which silicon is removed to reveal the buried features. An example of a suitable process for revealing buried features is described in the Applicant's patent application US 2015/0287637, the entire contents of which are herein incorporated by reference.

1. A method of smoothing a surface of a silicon substrate comprising the steps of:
providing a silicon substrate having a backside surface, wherein the silicon substrate has been ground to leave the backside surface with an associated roughness; and
smoothing the backside surface of the silicon substrate using a plasma etch process;
in which the plasma etch process comprises the steps of performing a first plasma etch step which forms a plurality of protrusions that upstand from the backside surface; and
performing a second plasma etch step which at least partially etches the protrusions to provide a smoothed backside surface which exhibits specular reflection.

2. A method according to claim 1 in which the first and second plasma etch steps are alternately repeated.

3. A method according to claim 1 in which the first plasma etch step is an isotropic etch process.

4. A method according to claim 1 in which no RF bias or an RF bias power of less than 100 W is used during the first plasma etch step.

5. A method according to claim 1 in which the first plasma etch step uses a gas mixture comprising oxygen and at least one etchant precursor gas.

6. A method according to claim 5 in which the first plasma etch step uses flows of the etchant precursor gas and oxygen which have associated flow rates, and the flow rate of oxygen is greater than the flow rate of the etchant precursor gas.

7. A method according to claim 6 in which the flow rate of oxygen is at least three times the flow rate of the etchant precursor gas.

8. A method according to claim 1 in which the first plasma etch step uses a fluorine containing etchant precursor gas.

9. A method according to claim 8 in which the fluorine containing etchant precursor gas is SF₆.

10. A method according to claim 8 in which the fluorine containing etchant precursor gas is CF₄.

11. A method according to claim 1 in which the first plasma etch step produces a plurality of deposits on the backside surface which act to mask the protrusions.

12. A method according to claim 1 in which the second plasma etch step uses a fluorine containing etchant precursor gas.

13. A method according to claim 12 in which the fluorine containing etchant precursor gas is SF₆ or CF₄.

14. A method according to claim 1 in which the second plasma etch step is performed in the substantial absence of oxygen.

15. A method according to claim 1 in which an RF bias power is used during the second plasma etch step.

16. A method according to claim 15 in which the RF bias power used during the second plasma etch step is greater than 500 W.

17. A method according to claim 1 in which the plasma etch process results in a reduction of the thickness of the substrate and the first plasma etch step accounts for less than 20% of the reduction.

18. A method according to claim 1 in which the silicon substrate provided has a periodic scratch pattern on the backside surface, and the step of smoothing is performed so as to remove the periodic scratch pattern.

19. A method according to claim 1 in which the first plasma etch step comprises two or more different first etches, wherein each of the first etches has different associated etch conditions and/or the second plasma etch step comprises two or more different second etches, wherein each of the second etches has different associated etch conditions.

20. An apparatus for smoothing a surface of a silicon substrate using a method according to claim 1, the apparatus comprising:
a chamber in which the plasma etch process is performed;
one or more plasma production devices for producing plasmas suitable for performing the first and second plasma etch steps; and
a controller configured to control the apparatus to performed the method according to claim 1.
